(19) United States
(12) Patent Application Publication
(10) Pub. No.: US 2025/0275279 A1
(43) Pub. Date: Aug. 28, 2025

(54) OPTOELECTRONIC DEVICE

(71) Applicant: STMicroelectronics International N.V., Geneva (CH)

(72) Inventors: Raul Andres BIANCHI, Myans (FR); Dominique GOLANSKI, Gieres (FR); Pierre TOURON, Grenoble (FR); Sara PELLEGRINI, Edinburgh (GB)

(73) Assignee: STMicroelectronics International N.V., Geneva (CH)

(21) Appl. No.: 19/052,720

(22) Filed: Feb. 13, 2025

(30) Foreign Application Priority Data
Feb. 27, 2024 (FR) FR2401885

(51) Int. Cl. H10F 39/00; H10F 30/225

(52) U.S. Cl. CPC H10F 39/807; H10F 30/225; H10F 39/811

(57) ABSTRACT

An avalanche diode for an optoelectronic device is formed in a substrate and includes a first doped region of a first conductivity type, flush with a first surface of the substrate, and a second doped region of a second conductivity type, the second doped region extending from the first doped region to a second surface of the substrate. The second doped region includes: a first sub-region flush with the second surface of the substrate, a second sub-region in contact with the first region, and a third sub-region between the first and second sub-regions. The first sub-region is more heavily doped than the second sub-region. On side of the second surface of the substrate, a common electrode including a metal element is provided within an isolating trench surrounding the avalanche diode and in contact with at least a portion of the flanks of the first sub-regions of the avalanche diode.

### PRIORITY CLAIM

This application claims the priority benefit of French Application for Patent No. 2401885, filed on Feb. 27, 2024, the content of which is hereby incorporated by reference in its entirety to the maximum extent allowable by law.

### TECHNICAL FIELD

The present disclosure generally concerns optoelectronic devices, and more particularly optoelectronic devices comprising a plurality of pixels, each comprising a single photon avalanche diode (SPAD).

### BACKGROUND

A SPAD photodiode is essentially formed of a PN junction reverse-biased to a voltage higher than its avalanche threshold. When no electric charge is present in the depletion area or space charge area of the PN junction, the photodiode is in a pseudo-stable, non-conductive state. When a photogenerated electric charge is injected into the depletion area, if the travel speed of this charge in the depletion area is sufficiently high, that is, if the electric field in the depletion area is sufficiently intense, the photodiode is likely to start an avalanche. A single photon is thus capable of generating a measurable electrical signal, and this, with a very short response time. SPAD photodiodes enable to detect radiation of very low light intensity, and are in particular used for single-photon detection and photon counting.

The forming of an image sensor comprising a plurality of pixels, each comprising a SPAD photodiode, is considered herein.

There is a need in the art to overcome all or part of the disadvantages of known devices comprising SPADs.

### SUMMARY

An embodiment provides an optoelectronic device comprising a plurality of avalanche diodes formed in a semiconductor substrate, each diode comprising in the substrate: a first doped region of a first conductivity type, flush with a first surface of the semiconductor substrate, and a second doped region of a second conductivity type opposite to the first conductivity type, the second doped region extending across the semiconductor substrate from the first doped region to a second surface of the semiconductor substrate, opposite to the first surface of the semiconductor substrate, wherein the second doped region comprises: a first sub-region flush with the second surface of the semiconductor substrate, a second sub-region in contact with the first sub-region, and a third sub-region extending between the first and second sub-regions, wherein the device comprises, on the side of the second surface of the substrate, a common electrode comprising a metal element in contact with at least a portion of the flanks of the first sub-regions of the diodes, and wherein the first sub-region is more heavily doped than the second sub-region of the second doped region.

According to an embodiment, the metal element is made of aluminum.

According to an embodiment, the metal element is formed as an extension of insulating trenches separating the avalanche diodes from one another.

According to an embodiment, the insulating trenches comprise an electrically-conductive core surrounded by an electrically-insulating sheath.

According to an embodiment, the insulating trenches are all continued by the metal element.

According to an embodiment, only part of the insulating trenches is continued by the metal element.

According to an embodiment, the metal element is continuous.

According to an embodiment, the metal element comprises a plurality of separate parts.

According to an embodiment, the separate parts of the metal element are electrically connected to one another by conductive elements.

According to an embodiment, the conductive elements are opaque.

Another embodiment provides a time-of-flight sensor comprising the optoelectronic device described hereabove.

Another embodiment provides a method of manufacturing an optoelectronic device comprising a plurality of avalanche diodes formed in a semiconductor substrate, each diode comprising in the substrate: a first doped region of a first conductivity type, flush with a first surface of the semiconductor substrate, and a second doped region of a second conductivity type opposite to the first conductivity type, the second region extending across the semiconductor substrate from the first region to a second surface of the semiconductor substrate, opposite to the first surface of the semiconductor substrate, wherein the second region comprises: a first sub-region flush with the second surface of the semiconductor substrate, a second sub-region in contact with the first region, and a third sub-region extending between the first and the second sub-region, the method comprising the forming, on the side of the second surface of the substrate, of a common electrode comprising a metal element in contact with at least a portion of the flanks of the first sub-regions of the diodes, and wherein the first sub-region is more heavily doped than the second sub-region of the second region.

According to an embodiment, the forming of the metal element comprises the following successive steps: a) forming an insulating trench in the conductive substrate, across the entire thickness of the semiconductor substrate, from the second surface of the substrate; b) etching an upper portion of the insulating trench on the side of the second surface of the semiconductor substrate, so as to form an opening and expose a portion of the flanks of the semiconductor substrate; and c) depositing a metal layer in the previously-formed opening.

According to an embodiment, the method comprises: between steps a) and b), depositing a transparent layer on the side of the second surface of the semiconductor substrate, and wherein etching step b) comprises etching the transparent layer, and after step c), forming conductive elements on top of and in contact with the metal layer.

According to an embodiment, the method comprises, after step c), depositing a transparent layer on the side of the second surface of the semiconductor substrate and forming conductive elements on top of and in contact with the transparent layer.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 is a cross-section view, partial and simplified, of an example of an optoelectronic device comprising SPADs;

FIG. 2 is another cross-section view, partial and simplified, of the optoelectronic device of FIG. 1;

FIG. 3A is a cross-section view, partial and simplified, of an example of the optoelectronic device of FIGS. 1 and 2 according to a first embodiment;

FIG. 3B is a cross-section view, partial and simplified, of the optoelectronic device of FIGS. 1 and 2, according to a second embodiment;

FIG. 3C is a cross-section view, partial and simplified, of an example of the optoelectronic device of FIGS. 1 and 2 according to a third embodiment;

FIGS. 4A to 4H are cross-section views illustrating steps of an example of a method of forming the device of FIGS. 1 and 2; and

FIGS. 5A to 5E are cross-section views illustrating steps of another example of a method of forming the device of FIGS. 1 and 2.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the forming of the circuits for controlling the pixels of the described devices has not been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

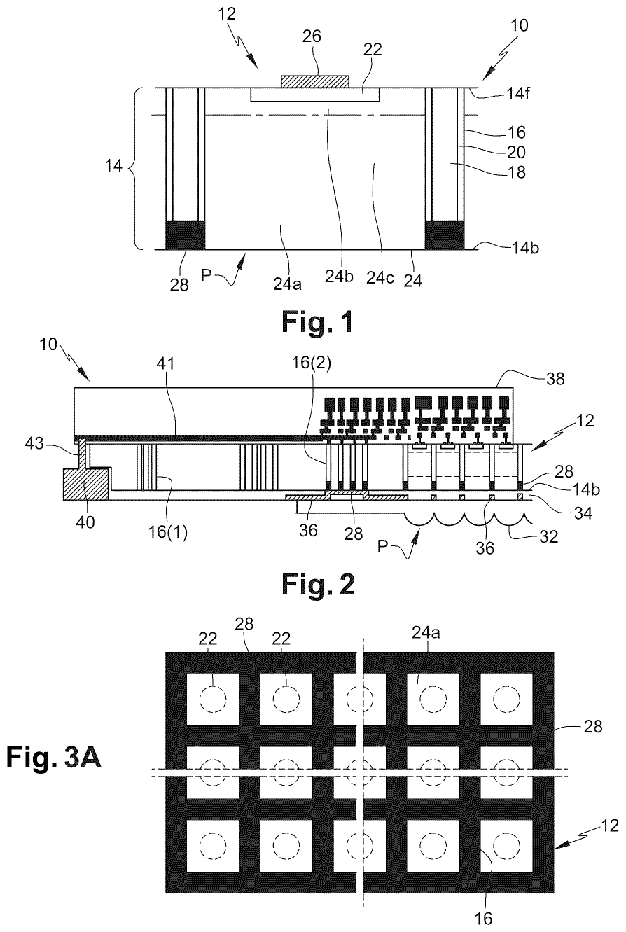

FIG. 1 is a cross-section view, partial and simplified, of an optoelectronic device 10 comprising SPADs 12 according to an embodiment. Device 10 is, for example, an image sensor.

Device 10 comprises, for example, a plurality of pixels P, for example arranged in an array. As an example, each pixel P comprises a single SPAD 12. In FIG. 1, three pixels P are shown, two of which are only partially shown. As an example, within the array, the repetition pitch of SPADs 12 is lower than 5 μm, for example lower than 3 μm.

SPADs 12 are formed in a semiconductor substrate 14. Semiconductor substrate 14 comprises a front surface 14f, the upper surface in the orientation of FIG. 1. Semiconductor substrate 14 comprises a rear surface 14b, opposite to front surface 14f, the lower surface in the orientation of FIG. 1. In this example, substrate 14 is configured to be illuminated from its rear surface 14b.

Each SPAD 12 is separated from adjacent SPADs 12, for example, by insulating trenches 16 extending from the front surface 14f of substrate 14 across the thickness of semiconductor substrate 14. Insulating trenches 16 form, for example, a grid pattern enabling to laterally insulate each SPAD 12. Each SPAD 12 is completely laterally surrounded and separated from the adjacent SPADs 12, for example, by insulating trenches 16. Insulating trenches 16 enable each SPAD 12 to be electrically and optically insulated, for example, from adjacent SPADs 12. As an example, insulating trenches 16 emerge onto the rear surface 14b of substrate 14. Semiconductor substrate 14 is, for example, made of silicon. Substrate 14 has a thickness in the range from 1 μm to 20 μm, for example in the range from 5 to 15 μm, for example in the order of 10 μm.

Insulating trenches 16 comprise, for example, a core 18 surrounded by a sheath 20. Core 18 is preferably completely laterally surrounded by sheath 20. The side walls of core 18 are preferably completely covered by sheath 20. As an example, the upper surface of core 18 and the upper surface of sheath 20 emerge onto the upper surface of substrate 14.

As an example, core 18 is made of an electrically-conductive material, for example metallic. Preferably, core 18 is made of an opaque material. Core 18 is, for example, made of aluminum.

Sheath 20 enables, for example, to provide an electrical insulation of SPADs 12. Sheath 20 is, for example, made of a dielectric material. Sheath 20 comprises, for example, an oxide having a high dielectric permittivity. As an example, sheath 20 is made of alumina (Al₂O₃) and/or of silicon dioxide (SiO₂) and/or of hafnium oxide (HfO₂).

SPAD 12 comprises a first region 22 of substrate 14, flush with the front surface 14f of substrate 14. First region 22 is doped with a first conductivity type, for example type N. As an example, each SPAD 12 comprises a single first region 22. First region 22 extends, for example, across substrate 14 over a thickness in the range from 200 nm to 800 nm, for example in the order of 500 nm. As an example, first region 22 is substantially round in top view. As a variant, first region 22 may be substantially square in top view. First region 22 extends, for example, in top view, over an area smaller than the surface of the SPAD 12, so that first region 22 is not in contact with insulating trenches 16. First region 22 is, for example, heavily doped. For example, first region 22 has a dopant concentration in the range from 10¹⁹ atoms/cm³ to 10²⁰ atoms/cm³.

SPAD 12 further comprises a second region 24 of substrate 14, extending across substrate 14 from the front surface 14f of the substrate to its rear surface 14b. More precisely, second region 24 extends from the lower surface of first region 22 to the rear surface 14b of substrate 14 and also around first region 22 on the front surface 14f of substrate 14, flush with the front surface 14f of substrate 14. Second region 24 is doped with a second conductivity type opposite to the first conductivity type, for example type P.

Second region 24 comprises a first sub-region 24a flush with the rear surface 14b of substrate 14. First sub-region 24a for example extends, in top view, over the entire surface of SPAD 12. As an example, first sub-region 24a is in contact by its lateral flanks with the lateral flanks of the insulating trenches 16 surrounding it. First sub-region 24a has, for example, a gradual dopant concentration which increases close to the rear surface 14b of substrate 14. In other words, first sub-region 24a is more heavily doped on the side of its lower surface than on the side of its upper surface. First sub-region 24a is, for example, very heavily doped. First sub-region 24a has, for example, a dopant concentration in the vicinity of its lower surface substantially equal to the dopant concentration of first region 22. First sub-region 24a has, for example, in the vicinity of its lower surface, a dopant concentration in the range from 10¹⁸ atoms/cm³ to 10²⁰ atoms/cm³.

Second region 24 further comprises a second sub-region 24b in contact with first region 22. Second sub-region 24b extends, for example, across the substrate 14 from the front surface 14f of substrate 14 to an intermediate level located under the lower surface of first region 22. Second sub-region 24b extends, for example, around first region 22, that is, in second region 24 between first region 22 and insulating trenches 16 in second region 24. Second sub-region 24b further extends below first region 22 between the lower surface of first region 22 and the intermediate level of substrate 14. As an example, the side walls of first region 22 and the bottom of first region 22 are in contact with the second sub-region 24b of second region 24. The junction between first region 22 and the second sub-region 24b of second region 24 corresponds to the PN junction of SPAD 12. First sub-region 24a is more heavily doped than the second sub-region 24b of second region 24. Second sub-region 24b is, for example, heavily doped. Second sub-region 24b has, for example, a dopant concentration in the range from 10¹⁷ atoms/cm³ to 10¹⁸ atoms/cm³.

Second region 24 further comprises a third sub-region 24c extending between first sub-region 24a and second sub-region 24b. Third sub-region 24c is, for example, in contact by its lower surface with the upper surface of first sub-region 24a. Third sub-region 24c is, for example, in contact by its upper surface with the lower surface of second sub-region 24b. Third sub-region 24c extends, for example, over the entire surface of SPAD 12. Third sub-region 24c is, for example, in contact by its flanks with the flanks of insulating trenches 16. Third sub-region 24c is, for example, very lightly doped. Third sub-region 24c is, for example, less heavily doped than second sub-region 24b. Third sub-region 24c has, for example, a dopant concentration in the order of 10¹⁴ atoms/cm³.

As an example, insulating trenches 16 extend along the entire height of second sub-region 24b and of third sub-region 24c. As an example, insulating trenches 16 extend along part of the height of first sub-region 24a.

As an example, first region 22 corresponds to a cathode region of the SPAD and second region 24 corresponds to an anode region of the SPAD.

Device 10 comprises, for example, a cathode contact area on the front surface of substrate 14 via a metal pad 26. Metal pad 26 corresponds, for example, to a cathode electrode. As an example, metal pad 26 is in contact, by its lower surface, with the upper surface of first region 22. Metal pad 26 is, for example, centered on first region 22.

Device 10 further comprises an anode contact area on the side of the rear surface of substrate 14 via a metal element 28. Metal element 28 corresponds, for example, to an anode electrode. Metal element 28 is in contact, by its flanks, with the flanks of the first sub-region 24a of second region 24. Metal element 28 is formed, for example, in front of insulating trenches 16 or, in other words, vertically in line with insulating trenches 16. Metal element 28 is at least partially arranged in a lower portion of a trench extending vertically in substrate 14 from the rear surface of substrate 14, for example as an extension of insulating trenches 16 provided in an upper portion of the trench. Metal element 28 extends, for example, along all or part of the height of the first sub-region 24a of second region 24.

Metal element 28 extends, for example, across the entire width of insulating trenches 16 so as to electrically contact the first sub-regions of two adjacent SPADs 12. As an example, metal element 28 is in contact, by its upper surface, with the lower surface of insulating trenches 16. More specifically, metal element 28 is, for example, in mechanical and electrical contact with the core 18 of insulating trenches 16. As a variant, the lower surface of insulating trenches 16 and the upper surface of metal element 28 are separated by a layer, for example electrically insulating, for example an oxide layer.

The first sub-regions 24a of the SPADs 12 of device 10 are thus all coupled together by a common electrode formed by metal element 28. The first sub-regions 24a of SPADs 12 may be biased to a same voltage via the common electrode 28. Metal element 28 is, for example, a P-type dopant metal. The use of such a metal enables to increase the doping of the first sub-regions 24a in the vicinity of metal element 28 by the diffusion of the metal into the silicon of the substrate, thus improving the ohmic contact between metal element 28 and first sub-region 24a. Metal element 28 is, for example, made of aluminum (Al). The high dopant concentration in first sub-region 24a enables to improve the ohmic contact between metal element 28 and to ensure a good anode contacting. Further, the provided solution enables to provide for second sub-region 24b to be less heavily doped than first region 22. More generally, the provided solution, in which the contact on anode region 24a is taken on the side of the rear surface of substrate 14, allows a greater freedom as to the selection of the dopant element concentration in second sub-region 24b, and thus as to the setting of the avalanche threshold of the PN junction of the SPAD.

In this example, the device comprises no anode contacting element in contact with sub-region 24b on the side of the upper surface of the substrate.

This enables to decrease the bulk due to the contacting on the anode region of the SPAD photodiodes.

Preferably, the metal element 28 does not extend over the lower surface of first sub-regions 24a.

Each SPAD 12 is, for example, individually coupled or connected via its cathode electrode 26 to a node for applying a potential VC. The SPADs 12 are, for example, collectively coupled or connected via by common anode electrode 28 to a node for applying a potential VA. Potentials VA and VC enable to bias SPADs 12. For example, potential VA is zero and potential VC is a positive potential.

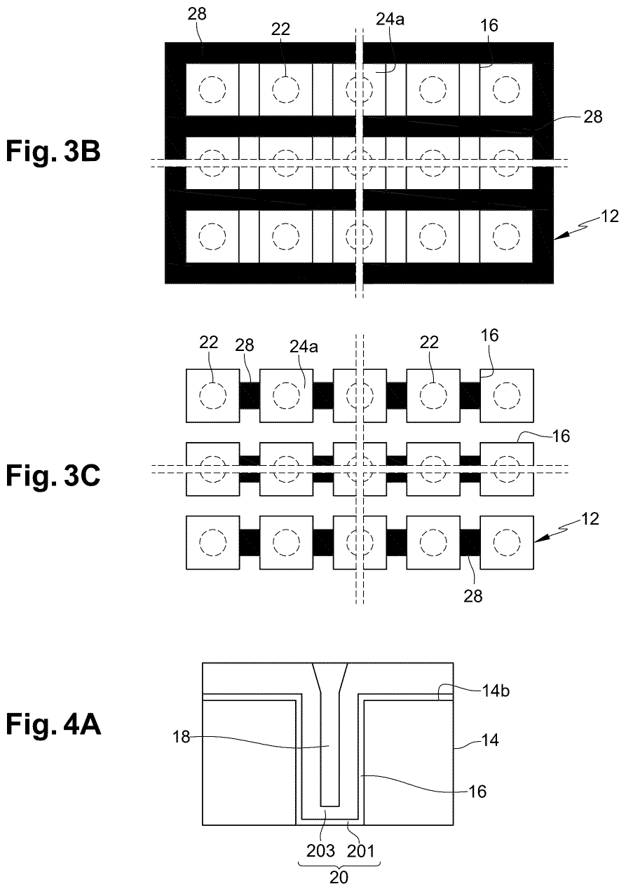

FIG. 2 is another cross-section view, partial and simplified, of the optoelectronic device 10 of FIG. 1.

Device 10 corresponds, for example, to a time-of-flight (ToF) sensor.

In the example of FIG. 2, each pixel P comprises a lens 32, for example a microlens, arranged in front of SPAD 12. Microlens 32 is, for example, formed on the rear surface 14b of semiconductor substrate 14.

Pixel array P further comprises, between SPADs 12 and microlenses 32, a layer 34 made of an optically transparent material having opaque elements 36 formed therein. Layer 34 is, for example, made of silicon dioxide. As an example, elements 36 optically delimit each pixel P and enable to limit cross-detections, that is, the detection by a SPAD 12 of a radiation running through the microlens 32 of the neighboring pixel P. As an example, elements 36 form a grid pattern superimposed on the grid pattern of insulating trenches 16, for example a grid pattern coinciding in top view with the grid pattern of insulating trenches 16. The elements 36 are, for example, metallic, for example made of tungsten (W).

In the example of FIG. 2, elements 36 are not in contact with metal element 28. As a variant, it may be provided for elements 36 to be in contact by their upper surfaces with the lower surface of metal element 28.

The device 10 of FIG. 2 further comprises, on the side of the upper surface of substrate 14, an interconnection stack 38. As an example, interconnection stack 38 comprises a stack of dielectric layers and of conductive levels, for example metallic, in which are formed connection elements intended to individually connect the cathode electrodes of the SPAD photodiodes to a control circuit.

At the periphery of pixel array P, device 10 comprises, for example, one or a plurality of pads 40. Pads 40 are, for example, located on the side of the rear surface 14b of substrate 14. Pads 40 are, for example, configured to be connected to an external device, for example by means of electrically-conductive wires, for example metal wires.

Pads 40 are preferably positioned out of line with SPADs 12 so as not to mask them. As an example, pads 40 are made of a metallic material, for example of aluminum.

Pads 40 are electrically connected to the common anode electrode 28 via conductive connection and routing elements detailed hereafter. At the periphery of pixel array P, device 10 further comprises a plurality of other insulating trenches 16 formed in substrate 14.

Some of these insulating trenches, designated with reference 16(1) in the drawing, for example enable to electrically insulate pixel array P from the rest of substrate 14.

Others of these insulating trenches, designated with reference 16(2) in the drawing, may be used as insulated conductive vias (that is, conductive vias surrounded by an insulating envelope) running through substrate 14. In the example of FIG. 2, these latter insulating trenches 16(2) are, for example, continued by portions of metal element 28, which extend laterally outside of pixel array P. They thus contribute to ensuring an electrical contact between pad 40 and the metal element, for example via conductive tracks.

As an example, the electrical connection between anode electrode 28 and pad(s)40 is performed via the portions of element 28 extending laterally outside of the pixel array, via the conductive cores of the trenches 16(2), via one or a plurality of conductive tracks 41 of interconnection stack 38, and via one or a plurality of insulated conductive vias 43 running through substrate 14.

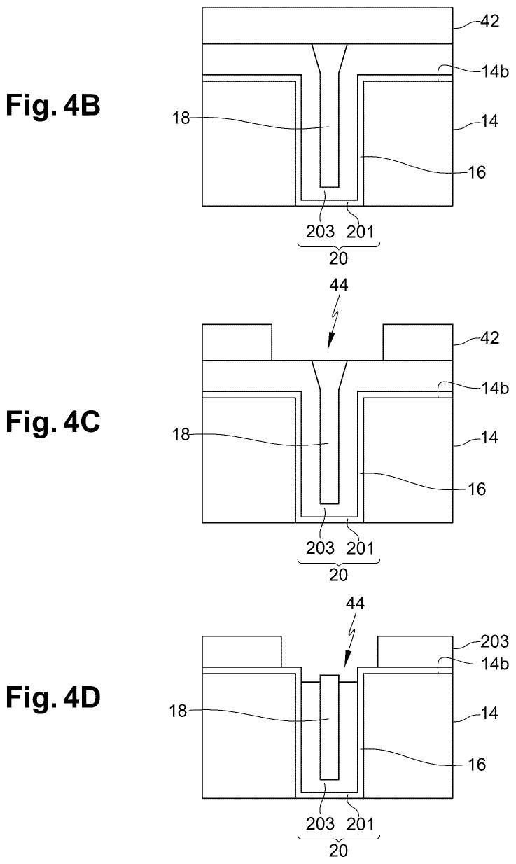

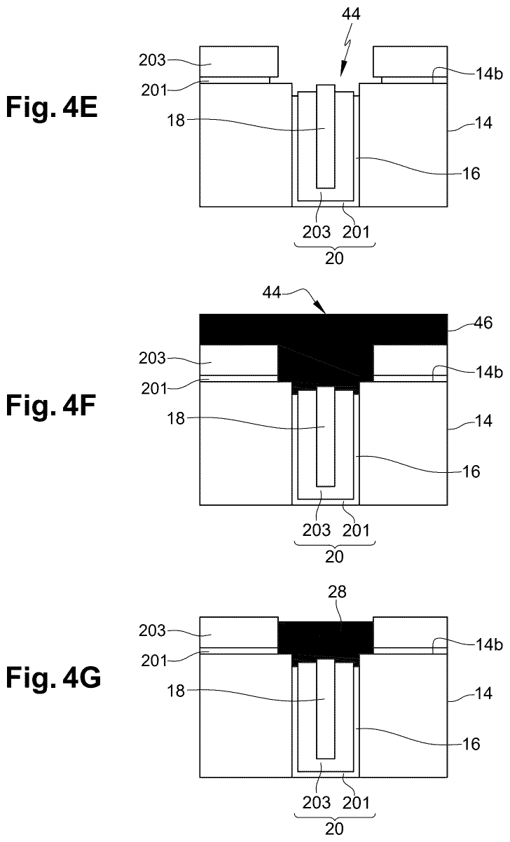

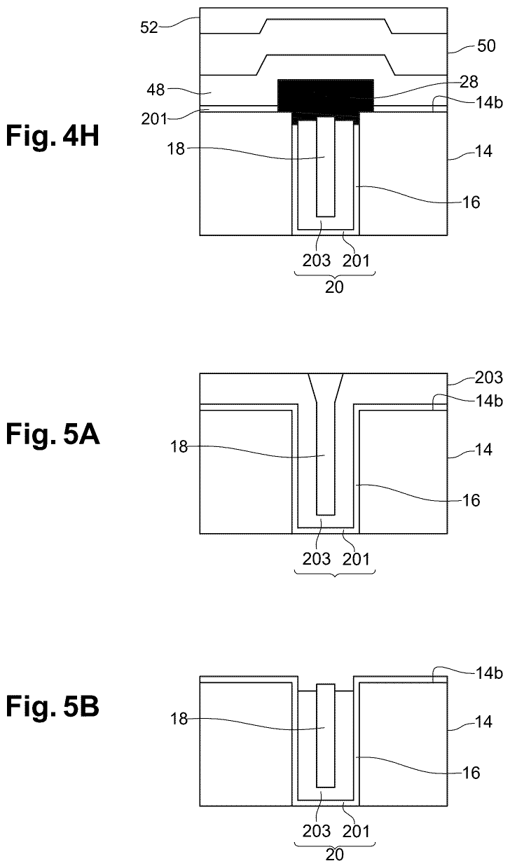

FIG. 3A, FIG. 3B, and FIG. 3C are horizontal cross-section views, partial and simplified, of examples of the optoelectronic device of FIGS. 1 and 2 according to different embodiments. More particularly, these drawings are bottom views along a horizontal cross-section plane corresponding to the plane of the surface 14b of substrate 14.

In FIG. 3A, FIG. 3B, and FIG. 3C, only the insulating trenches 16, the metal element 28, and the first sub-regions 24a of the second regions 24 of the SPADs of pixels P are shown. The first regions 22 of the SPADs (not shown in the cross-section plane) have further been schematically shown by dashed lines.

According to a first embodiment, illustrated in FIG. 3A, metal element 28 is formed opposite all the insulating trenches 16. Metal element 28 then forms a grid pattern substantially coinciding (in bottom view) with the grid pattern formed by insulating trenches 16 around SPADs 12. Metal element 28 is continuous and is not interrupted.

According to a second embodiment, illustrated in FIG. 3B, metal element 28 is formed in front of only part of insulating trenches 16. In the second embodiment, SPADs 12 are all in contact, via the flanks of first sub-region 24a, with metal element 28. In this embodiment, each SPAD 12 does not have all the lateral flanks of its first sub-region 24a in contact with metal element 28. In other words, in this embodiment, each SPAD 12 has only a portion of the lateral flanks of its first sub-region 24a in contact with metal element 28. As an example, it is provided for metal element 28 to extend, in top view, along the perimeter of pixel array P and only between rows of pixels P. As a variant, it may be provided for metal element 28 to extend, in top view, along the perimeter of pixel array P and only between columns of pixels P. In this embodiment, metal element 28 is continuous so that the portions of metal element 28 are all connected together.

According to a third embodiment, illustrated in FIG. 3C, metal element 28 comprises a plurality of separate parts. Thus, the third embodiment differs from the second embodiment in that metal element 28 is not continuous. In this embodiment, the individual parts of metal element 28, and thus areas 24a, are electrically connected to one another by conductive elements of another conductive level, for example corresponding to the element 36 described in relation with FIG. 2. The different parts of metal element 28 are thus all electrically connected to one another via element 36.

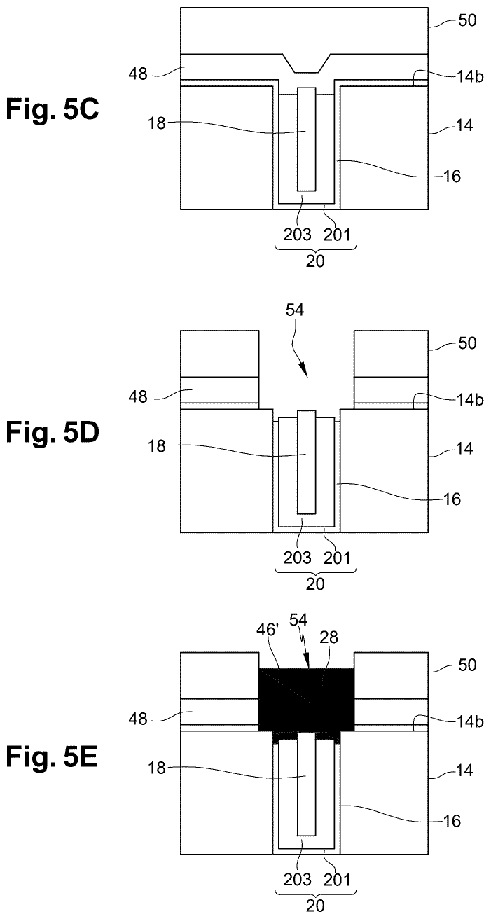

FIGS. 4A to 4H are cross-section views illustrating steps of an example of a method of forming the device of FIGS. 1 and 2.

More specifically, FIGS. 4A to 4H illustrate steps of a method of manufacturing metal element 28 in front of insulating trenches 16.

In FIGS. 4A to 4H, the orientation of the drawings is reversed with to what has been shown in FIGS. 1 and 2. The upper surface of the structure of FIGS. 4A to 4H corresponds to the rear surface of the structure and the lower surface of the structure of FIGS. 4A to 4H corresponds to the front surface of the structure.

FIG. 4A illustrates an initial structure in which insulating trenches 16 have been formed in semiconductor substrate 14.

This initial structure corresponds, for example, to a semiconductor substrate 14 on which an interconnection stack 38 (not shown in FIG. 4A) has been formed on the side of the front surface. After the forming of the interconnection stack, the substrate has been turned upside down and thinned from its rear surface, after which insulating trenches 16 have been formed on the side of the rear surface of the thinned substrate.

The forming of insulating trenches 16 comprises, for example, a step of etching of substrate 14 from its rear surface to create openings emerging, for example, onto interconnection stack 38. The forming of trenches 16 further comprises a step of deposition of a first underlayer 201, in contact with semiconductor substrate 14, and of deposition of a second underlayer 203 in contact with first underlayer 201. First underlayer 201 is deposited, for example, at the bottom of the openings, for example in contact with the interconnection stack, and on the flanks of the openings and the rear surface of substrate 14, in contact with substrate 14. Second underlayer 203 is deposited, for example, in the openings and on the side of the rear surface of substrate 14, in contact with first underlayer 201. First underlayer 201 and second underlayer 203 form, for example, in the openings, the insulating sheath 20 of insulating trenches 16. First underlayer 201 is, for example, made of alumina. Second underlayer 203 is, for example, made of silicon dioxide. The forming of trenches 16 further comprises a step of deposition of a metal layer in the openings and on the side of the rear surface of substrate 14, in contact with the second underlayer, and then a polishing step so that the metal layer is only kept in the openings. The metal layer then corresponds to the core 18 of insulating trenches 16.

FIG. 4B illustrates a structure obtained at the end of a step of deposition of a masking layer 42 on the upper surface of the structure illustrated in FIG. 4A. Masking layer 42 is, for example, made of a material sensitive to light rays, for example to ultraviolet (UV) rays. Masking layer 42 is, for example, made of a resin. As an example, the masking layer is made of a positive resin. During this step, masking layer 42 is, for example, deposited over the entire wafer surface.

FIG. 4C illustrates a structure obtained at the end of a step of photolithography of the structure illustrated in FIG. 4B. More specifically, during this step, the structure illustrated in FIG. 4B, more precisely masking layer 42, is exposed via its upper surface to a radiation, for example a UV ray. As an example, the exposure is carried out through a mask so as to only locally expose masking layer 42. This step is, for example, followed by a rinsing step enabling to remove the portion of masking layer 42 which has been exposed and to form in masking layer 42 one or a plurality of openings 44.

FIG. 4D illustrates a structure obtained at the end of a step of etching of the structure illustrated in FIG. 4C. More specifically, during this step, a portion of insulating trench 16 is removed in front of the opening 44 formed in masking layer 42. During this step, an upper portion of the second underlayer 203 and of core 18 is thus locally removed opposite opening 44. As an example, the etching is, here, selective over the first underlayer 201 of the sheath 20 of insulating trench 16. This underlayer 201 is, for example, kept during this step. During this step, masking layer 42 is, for example, consumed.

FIG. 4E illustrates a structure obtained at the end of another step of etching of the structure illustrated in FIG. 4D. More specifically, during this step, an upper portion of the first underlayer 201 of sheath 20 is removed from insulating trench 16, opposite what has been removed from the second underlayer 203. During this step, underlayer 203 is used, for example, as an etch mask. At the end of this step, a portion of the side wall of semiconductor substrate 14 is then exposed and free. As an example, during this step, a cleaning operation is further carried out to clean the flanks of substrate 14. This cleaning step enables, for example, to remove particles originating from the etch steps and present on the flanks of substrate 14. Such particles may, for example, decrease the ohmic contact between substrate 14 and metal element 28 if they are not removed. The cleaning step corresponds, for example, to a basic cleaning of SC1 (Standard Cleaning 1) type. As an example, an SC1 cleaning corresponds to a cleaning with ammonia and hydrogen peroxide.

FIG. 4F illustrates a structure obtained at the end of a step of deposition of a layer made of a metallic material 46. As an example, the deposition of metal layer 46 is performed by chemical vapor deposition (CVD). Metal layer 46 is, for example, deposited on the upper surface of the structure illustrated in FIG. 4E, and more particularly in the openings previously formed in layers 201 and 203. During this step, metal layer 46 is, for example, deposited in contact with flanks of substrate 14. As an example, during this step, metal layer 46 is deposited in contact with the upper surface of core 18. As a variant, it may be provided for metal layer 46 not to be in direct (electrical and mechanical) contact with the core 18 of insulating trench 16, but to be so via an insulating layer. The insulating layer is, for example, an oxide layer formed during the different cleaning operations described hereabove. The step of deposition of metal layer 46 is, for example, carried out under a temperature in the range from 200° C. to 400° C., for example in the order of 300° C.

FIG. 4G illustrates a structure obtained at the end of a step of polishing of the upper surface of the structure illustrated in FIG. 4F. More precisely, during this step, a portion of metal layer 46 is removed to expose the upper surface of the second underlayer 203 of the sheath 20 of insulating trench 16. This removal is, for example, carried out by chemical mechanical polishing (CMP). At the end of this step, what remains of metal layer 46 corresponds to metal element 28. In the example shown at the end of this step, the upper surface of metal element 28 is slightly recessed with respect to the upper surface of the second underlayer 203 of the sheath 20 of insulating trench 16. This recess is due to the fact that the polishing step is chemically assisted and that the solution used tends to etch metal layer 46 more than the second underlayer 203 of sheath 20.

FIG. 4H illustrates a structure obtained at the end of a step of removal of the second underlayer 203 of sheath 20 formed at the surface of substrate 14 and of a step of deposition of three successive layers 48, 50, and 52. As an example, during this step, the portion of the second underlayer 203 of sheath 20 present on the upper surface of semiconductor substrate 14, around the metal element 28, is removed.

At the end of the removal step, a first layer 48 is, for example, deposited on the upper surface of the structure. First layer 48 is, for example, deposited all over the wafer surface. First layer 48 is, for example, deposited so as to cover the upper surface of the first underlayer 201 of sheath 20 and the upper surface and a portion of the flanks of metal element 28. As an example, first layer 48 is in contact with the upper surface of underlayer 201 and the upper surface and the flanks of metal element 28. First layer 48 is, for example, an anti-reflective layer. First layer 48 is, for example, made of a material having a high dielectric permittivity. As an example, first layer 48 is made of alumina and/or of silicon dioxide and/or of hafnium oxide.

During this step, a second layer 50 is further deposited on the upper surface of layer 48. Second layer 50 is, for example, deposited in contact with layer 48. As an example, layer 50 is deposited over the entire wafer surface. As an example, layer 50 enables to provide a sufficient distance between SPADs and microlenses, which will be formed subsequently on the side of the rear surface of the structure. Layer 50 is, for example, made of silicon dioxide.

During this step, a third layer 52 is further deposited on the upper surface of layer 50. Third layer 52 is, for example, deposited in contact with layer 50. As an example, layer 52 is deposited over the entire wafer surface. As an example, layer 52 corresponds, at the end of an etch step, to the elements 36 illustrated in FIG. 2.

The method illustrated in relation with FIGS. 4A to 4H may, for example, be implemented to manufacture the device of FIGS. 1 and 2 according to the embodiments of FIGS. 3A and 3B.

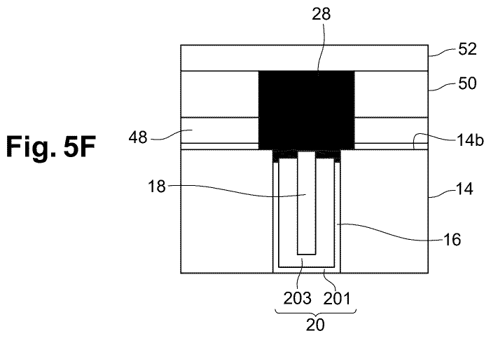

FIGS. 5A to 5F are cross-section views illustrating steps of another example of a method of forming the device of FIGS. 1 and 2.

More particularly, FIGS. 5A to 5F illustrate steps of a method of manufacturing metal element 28 in front of insulating trenches 16, different from the method illustrated in relation with FIGS. 4A to 4H in that, in the manufacturing method illustrated in FIGS. 5A to 5F, elements 36 are formed in contact with metal element 28.

In FIGS. 5A to 5F, similarly to what has been described in relation with FIGS. 4A to 4H, the orientation of the structures is reversed with respect to what has been shown in FIGS. 1 and 2.

FIG. 5A shows an initial structure identical to the initial structure illustrated in FIG. 4A.

FIG. 5B illustrates a structure obtained at the end of a step of etching of the second underlayer 203 of sheath 20 and of the core 18 of FIG. 5A. This step is, for example, similar to the step of etching of these same layers, which has been described in relation with FIG. 4D, with the difference that the etching described in relation with FIG. 5B is performed with no etch mask.

FIG. 5C illustrates a structure obtained at the end of a step of deposition of two layers 48 and 50 similar to the layers 48 and 50 illustrated in FIG. 4H, with the difference that they are, during the step illustrated in relation with FIG. 5C, deposited before the forming of metal element 28.

FIG. 5D illustrates a structure obtained at the end of a step of etching of layers 48, 50, and 201. More specifically, during this step, three successive etch steps are carried out to form an opening 54 successively in layer 50, layer 48, and first underlayer 201. The etching of layer 50 is, for example, carried out through a resin masking layer (not shown) previously deposited on the upper surface of the structure illustrated in FIG. 5C. As an example, at the end of this step, part of the flanks of substrate 14 are exposed and free.

FIG. 5E illustrates a structure obtained at the end of a step of forming of metal element 28 in opening 54. During this step, a layer 46′ made of a metallic material is, for example, deposited on the upper surface of the structure illustrated in FIG. 5D, and more particularly on the upper surface of layer 50 and in opening 54, similarly to what has been described for layer 46 in relation with FIG. 4F. A polishing is then performed to only keep layer 46′ in opening 54, similarly to what has been described in relation with FIG. 4G. What remains of layer 46′ then corresponds to metal element 28.

FIG. 5F illustrates a structure obtained at the end of a step of forming of a layer 52 similar to the layer 52 illustrated in FIG. 4H, with the difference that it is deposited on top of and in contact with the upper surface of metal element 28.

The method illustrated in relation with FIGS. 5A to 5F may, for example, be implemented to manufacture the device of FIGS. 1 and 2 according to the embodiments of FIGS. 3A, 3B, and 3C.

An advantage of the described embodiments is that the anode contacting on the rear surface 14b of substrate 14 enables to decrease the surface area of SPADs 12 and thus to decrease the surface area of the sensors.

Another advantage of the described embodiments is that the anode contacting on the rear surface 14b of substrate 14 enables to keep a distance between the anode contacting area and that of the cathode which enables to ensure a correct operation of the SPAD while limiting the risk of short-circuits, and this, despite the decrease in the surface area of SPAD 12.

Still another advantage of the described embodiments is that the anode contacting on the flanks of substrate 14 as an extension of insulating trenches 16 enables not to mask the rear surface 14b of substrate 14, which thus remains accessible to light.

Various embodiments and variants have been described. Those skilled in the art will understand that certain features of these various embodiments and variants may be combined, and other variants will occur to those skilled in the art. In particular, the cathode and anode may be interchanged. First region 22 may thus be the anode of SPAD 12 and be P-type doped. Second region 24 may then be the cathode of SPAD 12 and be N-doped.

Finally, the practical implementation of the described embodiments and variants is within the abilities of those skilled in the art based on the functional indications given hereabove.

1. An optoelectronic device, comprising a plurality of avalanche diodes formed in a semiconductor substrate, wherein each avalanche diode comprises in the substrate:
a first doped region of a first conductivity type, the first doped region having a surface flush with a first surface of the semiconductor substrate; and
a second doped region of a second conductivity type opposite to the first conductivity type, the second doped region extending across the semiconductor substrate from the first doped region to a second surface of the semiconductor substrate that is opposite to the first surface of the semiconductor substrate;
wherein the second doped region comprises:
a first sub-region having a surface that is flush with the second surface of the semiconductor substrate;
a second sub-region in contact with the first doped region; and
a third sub-region extending between the first and second sub-regions;
wherein the first sub-region is more heavily doped than the second sub-region; and
a common electrode for the optoelectronic device on the side of the second surface of the semiconductor substrate comprising a metal element in contact with at least a portion of flanks of the first sub-regions of adjacent avalanche diodes.

2. The optoelectronic device according to claim 1, wherein the metal element is made of aluminum.

3. The optoelectronic device according to claim 1, wherein the metal element is formed as an extension of insulating trenches separating the avalanche diodes from one another, with the metal element being laterally in contact with said portion of flanks for at least two adjacent avalanche diodes.

4. The optoelectronic device according to claim 3, wherein the insulating trenches comprise an electrically-conductive core surrounded by an electrically-insulating sheath.

5. The optoelectronic device according to claim 3, wherein the insulating trenches are all continued by the metal element.

6. The optoelectronic device according to claim 3, wherein only part of the insulation trenches is continued by the metal element.

7. The optoelectronic device according to claim 5, wherein the metal element is continuous.

8. The optoelectronic device according to claim 6, wherein the metal element comprises a plurality of separate parts.

9. The optoelectronic device according to claim 8, wherein the separate parts of the metal element are electrically connected to one another by conductive elements.

10. The optoelectronic device according to claim 9, wherein the conductive elements are opaque.

11. A time-of-flight sensor comprising the optoelectronic device according to claim 1.

12. A method of manufacturing an optoelectronic device that includes a plurality of avalanche diodes formed in a semiconductor substrate, each avalanche diode comprising in the semiconductor substrate: a first doped region of a first conductivity type flush with a first surface of the semiconductor substrate, and a second doped region of a second conductivity type opposite to the first conductivity type, the second region extending across the semiconductor substrate from the first region to a second surface of the semiconductor substrate, opposite to the first surface of the semiconductor substrate, wherein the second region comprises: a first sub-region flush with the second surface of the semiconductor substrate, a second sub-region in contact with the first region, and a third sub-region extending between the first and the second sub-region, the method comprising:
forming, on the side of the second surface of the semiconductor substrate, a common electrode comprising a metal element in contact with at least a portion of the flanks of the first sub-regions of the diodes; and
wherein the first sub-region is more heavily doped than the second sub-region.

13. The method of manufacturing a device according to claim 12, wherein forming the metal element comprises the following successive steps:
a) forming an insulating trench extending across the entire thickness of the semiconductor substrate from the second surface;
b) etching an upper portion of the insulating trench on the side of the second surface of the semiconductor substrate so as to form an opening and expose a portion of the flanks of the semiconductor substrate; and
c) depositing a metal layer in the opening.

14. The method of manufacturing a device according to claim 13, comprising:
between steps a) and b), depositing a transparent layer on the side of the second surface of the semiconductor substrate;
wherein etching step b) comprises etching the transparent layer; and
after step c), forming of conductive elements on top of and in contact with the metal layer.

15. The method of manufacturing a device according to claim 13, comprising after step c), depositing a transparent layer on the side of the second surface of the semiconductor substrate and forming conductive elements on top of and in contact with the transparent layer.

16. An avalanche diode, comprising;
a portion of a semiconductor substrate surrounded by an isolating trench;
wherein said portion includes:
a first doped region of a first conductivity type at first surface of the semiconductor substrate; and
a second doped region of a second conductivity type opposite to the first conductivity type in contact with the first doped region and extending to a second surface of the semiconductor substrate opposite the first surface;
wherein the second doped region comprises:
a first sub-region having a surface that is flush with the second surface of the semiconductor substrate;
a second sub-region in contact with the first doped region; and
a third sub-region extending between the first and second sub-regions;
wherein the first sub-region is more heavily doped than the second sub-region; and
wherein the isolating trench comprises an upper portion filled with an insulated electrode and a lower portion filled with a metal element in physical and electrical contact with flanks of the first sub-region.

17. The avalanche diode of claim 16, wherein the metal element is electrically connected to the insulated electrode.

18. The avalanche diode of claim 16, wherein the metal element is electrically insulated from the insulated electrode.

19. The avalanche diode of claim 16, wherein the insulated electrode comprises an electrically-conductive core surrounded by an electrically-insulating sheath isolating the electrically-conductive core from flanks of at least the first and second sub-regions.
